(19) United States
(12) Patent Application Publication
(10) Pub. No.: US 2026/0164943 A1
(43) Pub. Date: Jun. 11, 2026

(54) DISPLAY APPARATUS

(71) Applicant: Samsung Display Co., LTD., Yongin-si (KR)

(72) Inventor: Jaehoon Kim, Yongin-si (KR)

(21) Appl. No.: 19/380,164

(22) Filed: Nov. 5, 2025

(30) Foreign Application Priority Data
Nov. 7, 2024 (KR) 10-2024-0157465

(51) Int. Cl. H10K 59/122; H10K 50/115; H10K 59/80

(52) U.S. Cl. CPC H10K 59/122; H10K 59/873; H10K 50/115

(57) ABSTRACT

Provided is a display apparatus including a substrate, a pixel-defining layer including an opening and disposed on the substrate, a light-emitting element overlapping the opening of the pixel-defining layer and including a pixel electrode, an emission layer, and an opposite electrode, a capping layer disposed on the light-emitting element, a transparent film disposed on the capping layer and including a plurality of openings, and an auxiliary layer disposed in the plurality of openings of the transparent film and overlapping the opening of the pixel-defining layer.

This application claims priority to Korean Patent Application No. 10-2024-0157465, filed on Nov. 7, 2024, and all the benefits accruing therefrom under 35 U.S.C. § 119, the content of which in its entirety is herein incorporated by reference.

### BACKGROUND

### 1. Field

One or more embodiments relate to a display apparatus.

### 2. Description of the Related Art

A display apparatus visually displays data. Display apparatuses may display images using light-emitting diodes. The purpose of a display apparatus has diversified, and various attempts have been made to designing a display apparatus having improved display quality.

### SUMMARY

One or more embodiments include a display apparatus.

Additional aspects will be set forth in part in the description which follows and, in part, will be apparent from the description, or may be learned by practice of the presented embodiments of the disclosure.

According to one or more embodiments, a display apparatus includes a substrate, a pixel-defining layer including an opening and disposed on the substrate, a light-emitting element overlapping the opening of the pixel-defining layer and including a pixel electrode, an emission layer, and an opposite electrode, a capping layer disposed on the light-emitting element, a transparent film disposed on the capping layer and including a plurality of openings, and an auxiliary layer disposed in the plurality of openings of the transparent film and overlapping the opening of the pixel-defining layer.

According to an embodiment, respective areas of the auxiliary layer disposed in the plurality of openings of the transparent film may each be greater than an area of the opening of the pixel-defining layer.

According to an embodiment, the auxiliary layer may include an acidic material.

According to an embodiment, the auxiliary layer may include polyacrylic acid (PAA).

According to an embodiment, the auxiliary layer may include ethanol.

According to an embodiment, each of the plurality of openings of the transparent film may be provided in a polygonal shape.

According to an embodiment, each of the plurality of openings of the transparent film may be provided in a hexagonal shape.

According to an embodiment, each of the plurality of openings of the transparent film may be provided in a quadrangular shape.

According to an embodiment, each of the plurality of openings of the transparent film may be provided in a rhombus shape.

According to an embodiment, each of the plurality of openings of the transparent film may be provided in a circular shape.

According to an embodiment, the emission layer may include quantum dots.

According to an embodiment, a diameter of each of the plurality of openings of the transparent film may be 10 μm or more.

According to an embodiment, the transparent film may include polyvinyl chloride (PVC).

According to an embodiment, the display apparatus may further include a thin-film encapsulation layer disposed on the auxiliary layer and the transparent film.

According to one or more embodiments, a display apparatus includes a substrate, a pixel-defining layer including an opening and disposed on the substrate, a light-emitting element overlapping the opening of the pixel-defining layer and including a pixel electrode, an emission layer, and an opposite electrode, a capping layer disposed on the light-emitting element, an auxiliary layer disposed on the capping layer and including an acidic material, and a transparent film disposed on the auxiliary layer, wherein the auxiliary layer is attached to a lower surface of the transparent film.

According to an embodiment, the auxiliary layer may be coated onto an entirety of the lower surface of the transparent film.

According to an embodiment, the auxiliary layer may include an acidic material.

According to an embodiment, the auxiliary layer may include ethanol.

According to an embodiment, the emission layer may include quantum dots.

According to an embodiment, the display apparatus may further include a thin-film encapsulation layer disposed on the transparent film.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a display apparatus according to an embodiment;

FIG. 2 is an equivalent circuit diagram of a pixel circuit electrically connected to a light-emitting element included in a pixel of the display apparatus of FIG. 1;

FIG. 3A is a schematic cross-sectional view of the display apparatus according to an embodiment, and FIG. 3B is a schematic cross-sectional view of a display apparatus according to another embodiment;

FIG. 4 is a schematic plan view of a display apparatus according to an embodiment;

FIG. 5 is a schematic cross-sectional view of a display apparatus according to an embodiment, taken along line I-I′ of FIG. 4;

FIGS. 6A to 6D are schematic plan views of a transparent film and an auxiliary layer according to embodiments;

FIG. 7 is a schematic cross-sectional view of a display apparatus according to an embodiment, taken along line I-I′ of FIG. 4; and

FIG. 8 is a schematic cross-sectional view of a transparent film and an auxiliary layer.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are described herein, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the written description. Effects and features of the disclosure, and methods for achieving them will be clarified with reference to embodiments described herein in detail with reference to the drawings. However, the disclosure is not limited to the following embodiments and may be embodied in various forms.

Hereinafter, embodiments will be described with reference to the accompanying drawings, wherein like reference numerals refer to like elements throughout and a repeated description thereof is omitted.

While such terms as “first” and “second” may be used to describe various elements, such elements must not be limited to the above terms. The above terms are used to distinguish one element from another.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or elements but do not preclude the addition of one or more other features or elements.

It will be further understood that, when a layer, region, or element is referred to as being “on” another layer, region, or element, it can be directly or indirectly on the other layer, region, or element. That is, for example, intervening layers, regions, or elements may be present.

The terms “about” or “approximately” as used herein are inclusive of the stated value and include a suitable range of deviation for the particular value as determined by one of ordinary skill in the art, considering the measurement in question and the error associated with measurement of the particular quantity. The terms “about” or “approximately” can mean within one or more standard deviations, or within ±30%, 20%, 10%, 5% of the stated value, for example.

Sizes of elements in the drawings may be exaggerated or reduced for convenience of explanation. As an example, the size and thickness of each element illustrated in the drawings are arbitrarily represented for convenience of description, and thus, the disclosure is not necessarily limited thereto.

In the case where a certain embodiment may be implemented differently, a specific process order may be performed in the order different from the described order. As an example, two processes successively described may be simultaneously performed substantially and performed in the opposite order.

In the present specification, “A and/or B” means A or B, or A and B. In the present specification, “at least one of A and B” means A or B, or A and B.

It will be understood that when a layer, region, or element is referred to as being “connected” to another layer, region, or element, it may be “directly connected” to the other layer, region, or element or may be “indirectly connected” to the other layer, region, or element with another layer, region, or element located therebetween. For example, it will be understood that when a layer, region, or element is referred to as being “electrically connected” to another layer, region, or element, it may be “directly electrically connected” to the other layer, region, or element or may be “indirectly electrically connected” to the other layer, region, or element with another layer, region, or element interposed therebetween.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different orientations that are not perpendicular to one another.

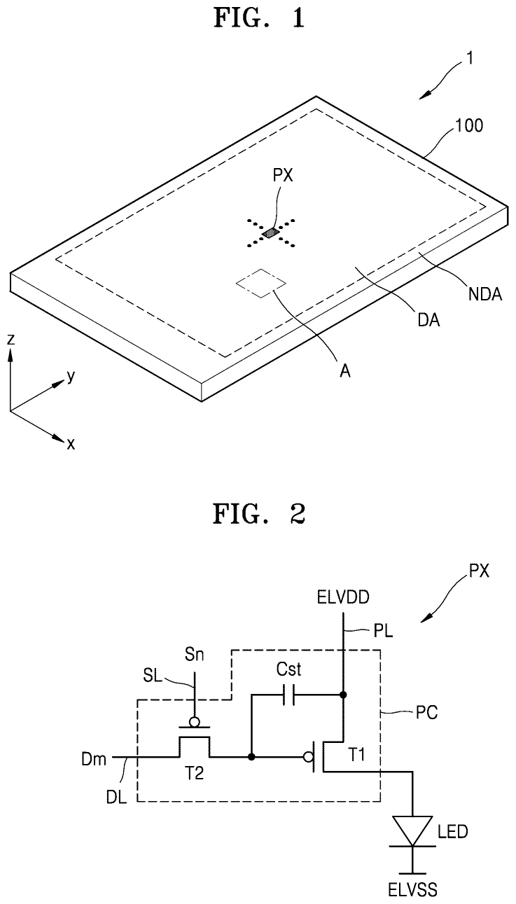

FIG. 1 is a schematic perspective view of a display apparatus 1 according to an embodiment.

Referring to FIG. 1, the display apparatus 1 may include a display area DA and a non-display area NDA in a substrate 100.

The display area DA may be configured to display images. A plurality of pixels PX disposed two-dimensionally may be disposed in the display area DA in a plan view. The display apparatus 1 may be configured to display images by using light emitted from the plurality of pixels PX.

The non-display area NDA is a region in which images are not displayed and the pixels PX are not disposed. The non-display area NDA may surround the display area DA entirely. A driver, a voltage line, or the like configured to provide electrical signals or power to pixels PX, may be disposed in the non-display area NDA. A pad section (not illustrated) may be included in the non-display area NDA, wherein the pad section is a region to which electronic elements or a printed circuit board may be electrically connected.

The display area DA may have a polygonal shape. As an example, as illustrated in FIG. 1, the display area DA may have a rectangular shape in which a horizontal length thereof is greater than a vertical length thereof. The display area DA may have a square shape. Alternatively, the display area DA may have various shapes such as, for example, an elliptical shape or a circular shape.

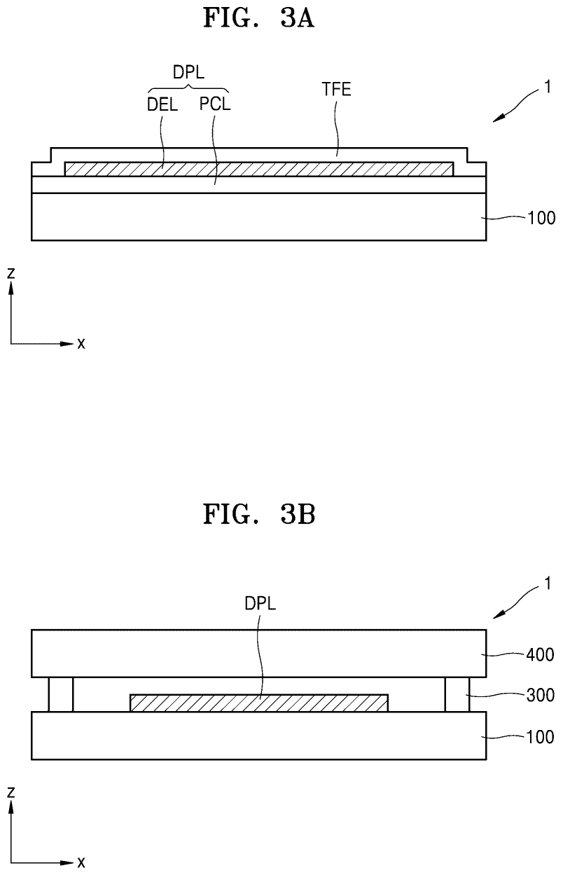

FIG. 2 is an equivalent circuit diagram of a pixel circuit electrically connected to a light-emitting element included in a pixel of the display apparatus 1 of FIG. 1.

Referring to FIG. 2, a pixel PX may include a pixel circuit PC and a display element connected to the pixel circuit PC, wherein the display element may be, for example, a light-emitting element LED. The pixel circuit PC may include a first thin-film transistor T1, a second thin-film transistor T2, and a storage capacitor Cst. Each pixel PX may emit, for example, red, green, or blue light, or emit red, green, blue, or white light by using the light-emitting element LED.

The second thin-film transistor T2 is a switching thin-film transistor, may be connected to a scan line SL and a data line DL, and configured to transfer a data voltage or a data signal Dm to the first thin-film transistor T1 according to a switching voltage or a switching signal Sn, the data voltage being input from the data line DL, and the switching voltage being input from the scan line SL. The storage capacitor Cst may be connected to the second thin-film transistor T2 and a driving voltage line PL and configured to store a voltage corresponding to a difference between a voltage transferred from the second thin-film transistor T2 and a first power voltage ELVDD supplied to the driving voltage line PL.

The first thin-film transistor T1 is a driving thin-film transistor, may be connected to the driving voltage line PL and the storage capacitor Cst, and configured to control a driving current according to the voltage stored in the storage capacitor Cst, the driving current flowing from the driving voltage line PL to the light-emitting element LED. The light-emitting element LED may be configured to emit light having a preset brightness corresponding to the driving current. An upper electrode (e.g., a cathode) of the light-emitting element LED may receive a second power voltage ELVSS.

Although it is illustrated in FIG. 2 that the pixel circuit PC includes two thin-film transistors and one storage capacitor, the number of thin-film transistors and the number of storage capacitors may be variously changed depending on the design of the pixel circuit PC.

FIG. 3A is a schematic cross-sectional view of the display apparatus 1 according to an embodiment, and FIG. 3B is a schematic cross-sectional view of the display apparatus 1 according to another embodiment.

Referring to FIG. 3A, the display apparatus 1 may include a display layer DPL and a thin-film encapsulation layer TFE on the substrate 100. The display layer DPL may include a pixel circuit layer PCL and a display element layer DEL, wherein the pixel circuit layer PCL includes a pixel circuit and insulating layers, and the display element layer DEL is disposed on the pixel circuit layer PCL and includes a plurality of display elements.

The substrate 100 may include glass, metal, or polymer resin. The polymer resin may include, for example, polyethersulphone, polyacrylate, polyetherimide, polyethylene naphthalate, polyethylene terephthalate, polyphenylene sulfide, polyarylate, polyimide, polycarbonate, cellulose acetate propionate, or a mixture thereof. The substrate 100 may have a multi-layered structure including two layers each including the polymer resin, and a barrier layer therebetween, the barrier layer including an inorganic material (such as, for example, silicon oxide (SiOₓ), silicon nitride (SiNₓ), and silicon oxynitride (SiON)). However, various modifications may be made.

The display element layer DEL may include display elements, for example, an organic light-emitting element, a quantum-dot light-emitting element, and the like. The pixel circuit layer PCL may include a pixel circuit connected to the light-emitting element, and insulating layers. As an example, the pixel circuit layer PCL may include a plurality of transistors, a plurality of storage capacitors, and insulating layers therebetween.

The display elements may be covered by an encapsulation member such as, for example, the thin-film encapsulation layer TFE. The thin-film encapsulation layer TFE may include at least one inorganic encapsulation layer and at least one organic encapsulation layer covering the display element layer DEL. The inorganic encapsulation layer may include at least one inorganic insulating material among aluminum oxide (Al₂O₃), titanium oxide (TiO₂), tantalum oxide (Ta₂O₅), hafnium oxide (HfO₂), zinc oxide (ZnOₓ), silicon oxide (SiOₓ), silicon nitride (SiNₓ), and silicon oxynitride (SiON). The organic encapsulation layer may include a polymer-based material. The polymer-based material may include an acryl-based resin, an epoxy-based resin, polyimide, and polyethylene. In an embodiment, the organic encapsulation layer may include acrylate.

Referring to FIG. 3B, the display apparatus 1 may include the display layer DPL and a sealing substrate 400 on the substrate 100. A sealing member 300 may be disposed between the substrate 100 and the sealing substrate 400. The sealing substrate 400 may be a transparent member. The substrate 100 and the sealing substrate 400 are coupled to each other by the sealing member 300, and an inner space between the substrate 100 and the sealing substrate 400 may be sealed. In this case, absorbents or fillers may be located in the inner space. The sealing member 300 may be sealant. In another embodiment, the sealing member 300 may include a material cured by a laser beam. As an example, the sealing member 300 may include frit. Specifically, the sealing member 300 may include an organic sealant such as, for example, a urethane-based resin, an epoxy-based resin, an acryl-based resin, or an inorganic sealant such as, for example, silicon. As a urethan-based resin, for example, urethane acrylate may be used. As acryl-based resin, for example, butyl acrylate, ethylhexyl acrylate, or the like may be used. The sealing member 300 may include a material cured by heat.

In an embodiment, the display element layer DEL may be covered by the thin-film encapsulation layer TFE of FIG. 3A, and the sealing substrate 400 and the sealing member 300 of FIG. 3B.

A touch electrode layer (not illustrated) may be disposed on the thin-film encapsulation layer TFE and/or the sealing substrate 400, and an optical functional layer (not illustrated) may be disposed on the touch electrode layer. The touch electrode layer may obtain coordinate information corresponding to an external input, for example, a touch event. The optical functional layer may reduce reflectivity of light (external light) incident toward the display apparatus 1 from the outside. Alternatively, the optical functional layer may increase color purity of light emitted from the display apparatus 1. In an embodiment, the optical functional layer may include a phase retarder and/or a polarizer. The phase retarder may include a film-type retarder or a liquid crystal coated-type retarder. The phase retarder may include a λ/2 phase retarder and/or a λ/4 phase retarder. The polarizer may include a film-type polarizer or a liquid crystal coated-type polarizer. The film-type polarizing layer may include a stretchable synthetic resin film, and the liquid crystal coated-type polarizing layer may include liquid crystals arranged in a preset arrangement. Each of the retarder and the polarizer may further include a protective film.

In another embodiment, the optical functional layer may include a black matrix and color filters. The color filters may be arranged by taking into account colors of light emitted respectively from the pixels of the display apparatus 1. The color filters may each include red, green, or blue pigment or dye. Alternatively, the color filters may each further include quantum dots in addition to the pigment or dye. Alternatively, some of the color filters may not include pigment or dye, and may include scattering particles such as, for example, titanium oxide.

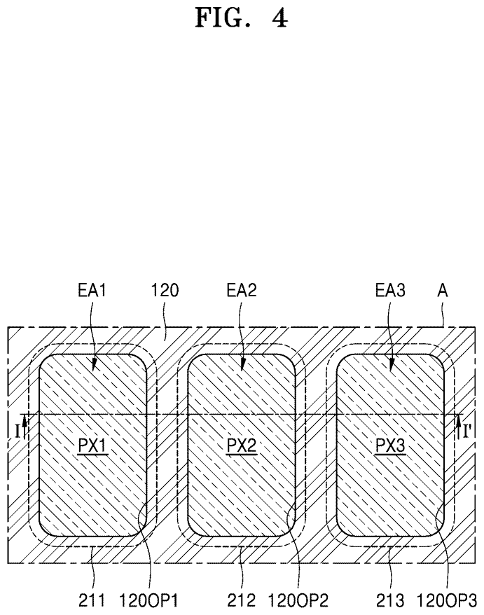

FIG. 4 is a schematic plan view of the display apparatus 1 according to an embodiment.

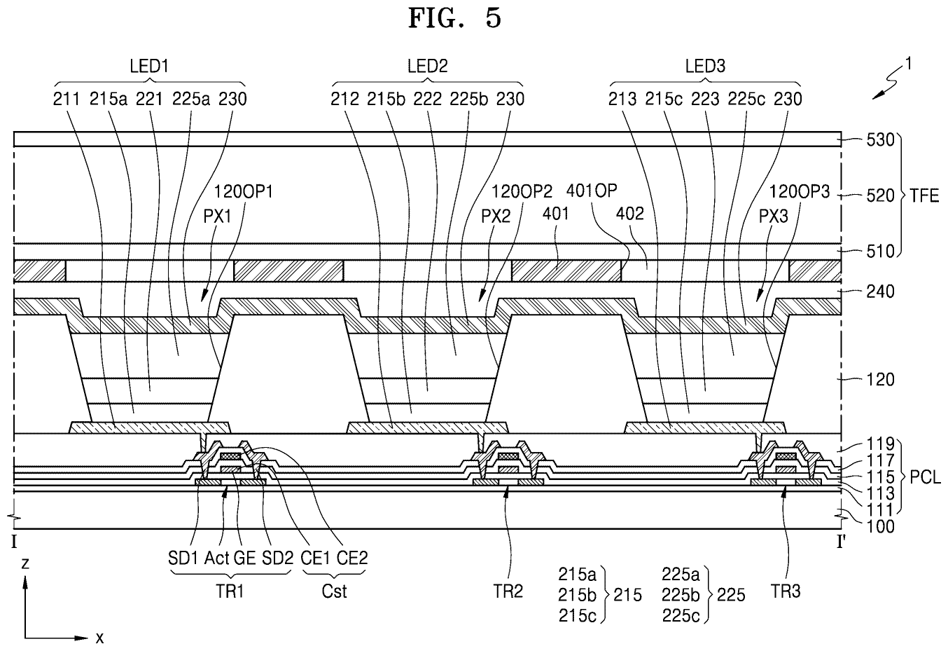

Referring to FIG. 4, the display apparatus 1 may include a plurality of pixels PX (see FIG. 1). The plurality of pixels PX (see FIG. 1) may include a first pixel PX1, a second pixel PX2, and a third pixel PX3. The first pixel PX1 may include a first light-emitting element LED1 (see FIG. 5), the second pixel PX2 may include a second light-emitting element LED2 (see FIG. 5), and the third pixel PX3 may include a third light-emitting element LED3. The first pixel PX1, the second pixel PX2, and the third pixel PX3 may be configured to emit light of different colors. As an example, although the first pixel PX1 may emit red light, the second pixel PX2 may emit green light, and the third pixel PX3 may emit blue light, this is just an example, and embodiments of the present disclosure are not limited thereto. As another example, the first pixel PX1 may emit green light, the second pixel PX2 may emit blue light, and the third pixel PX3 may emit red light. As another example, the first pixel PX1 may emit red light, the second pixel PX2 may emit blue light, and the third pixel PX3 may emit green light. Red light may be light in a wavelength band of about 580 nm to about 780 nm, blue light may be light in a wavelength band of about 380 nm to about 495 nm, and green light may be light in a wavelength band of about 495 nm to about 580 nm.

Each light-emitting element may include a lower electrode, an upper electrode, and an emission layer disposed between the lower electrode and the upper electrode. Accordingly, the first pixel PX1 may include a first pixel electrode 211 of the first light-emitting element LED1 (see FIG. 5), the second pixel PX2 may include a second pixel electrode 212 of the second light-emitting element LED2 (see FIG. 5), and the third pixel PX3 may include a third pixel electrode 213 of the third light-emitting element LED3 (see FIG. 5). The first pixel electrode 211, the second pixel electrode 212, and the third pixel electrode 213 may be apart from each other on the substrate 100 (see FIG. 5). In the present specification, “on a plane” means a plane viewed from a direction perpendicular to the substrate 100. That is, “A and B apart from each other on a plane” means “A and B apart from each other when viewed in a direction perpendicular to the substrate 100.”

A pixel-defining layer 120 may be disposed on the first pixel electrode 211, the second pixel electrode 212, and the third pixel electrode 213, and may cover the edges of each of the first pixel electrode 211, the second pixel electrode 212, and the third pixel electrode 213. The pixel-defining layer 120 may have a first opening 120OP1 exposing the central portion of the first pixel electrode 211, a second opening 120OP2 exposing the central portion of the second pixel electrode 212, and a third opening 120OP3 exposing the central portion of the third pixel electrode 213.

Although not illustrated in FIG. 4, emission layers that emit light may be respectively located in the first opening 120OP1, the second opening 120OP2, and the third opening 120OP3 of the pixel-defining layer 120. The upper electrode may be disposed on the emission layers. As described herein, a stack structure of the lower electrode, the emission layer, and the upper electrode may form one light-emitting element. One opening of the pixel-defining layer 120 may correspond to one light-emitting element and define one emission area.

As an example, an emission layer emitting red light may be disposed in the first opening 120OP1, and the first opening 120OP1 may define a first emission area EA1. Similarly, an emission layer emitting green light may be disposed in the second opening 120OP2, and the second opening 120OP2 may define a second emission area EA2. An emission layer emitting blue light may be disposed in the third opening 120OP3, and the third opening 120OP3 may define a third emission area EA3. Accordingly, the size of the area of the first opening 120OP1 may be the same as the size of the area of the first emission area EA1. The size of the area of the second opening 120OP2 may be the same as the size of the area of the second emission area EA2. The size of the area of the third opening 120OP3 may be the same as the size of the area of the third emission area EA3.

Each of the first opening 120OP1, the second opening 120OP2, and the third opening 120OP3 may have a polygonal shape when viewed in a direction (z axis direction) perpendicular to the substrate 100 (see FIG. 5). In other words, each of the first to third emission areas EA1, EA2, and EA3 may have a polygonal shape when viewed in the direction (z axis direction) perpendicular to the substrate 100. Although it is illustrated in FIG. 4 that each of the first to third emission areas EA1, EA2, and EA3 has a quadrangular shape, specifically, a quadrangular shape with round edges when viewed in the direction (z axis direction) perpendicular to the substrate 100, embodiments of the present disclosure are not limited thereto. As an example, each of the first to third emission areas EA1, EA2, and EA3 may have a circular shape or an elliptical shape when viewed in the direction (z axis direction) perpendicular to the substrate 100.

Although it is illustrated in FIG. 4 that the first pixel PX1, the second pixel PX2, and the third pixel PX3 are disposed in a stripe structure, embodiments of the present disclosure are not limited thereto. As an example, the first pixel PX1, the second pixel PX2, and the third pixel PX3 may be disposed in various pixel configuration structures such as, for example, a pentile™ structure, a mosaic structure, and a delta structure.

FIG. 5 is a schematic cross-sectional view of the display apparatus 1 according to an embodiment, taken along line I-I′ of FIG. 4.

Referring to FIG. 5, the display apparatus 1 may include the substrate 100, the pixel circuit layer PCL on the substrate 100, and the first to third light-emitting elements LED1, LED2, and LED3 on the pixel circuit layer PCL. In an embodiment, the display apparatus 1 may further include the thin-film encapsulation layer TFE on the first to third light-emitting elements LED1, LED2, and LED3.

The pixel circuit layer PCL may include first to third transistors TR1, TR2, and TR3, a buffer layer 111, a first gate insulating layer 113, a second gate insulating layer 115, an interlayer insulating layer 117, and a planarization layer 119 disposed under and/or on the elements of the transistor. Here, each of the first to third transistors TR1, TR2, and TR3 may correspond to the first thin-film transistor T1 illustrated in FIG. 2. Because the structure of the second transistor TR2 and the third transistor TR3 is equal or similar to the structure of the first transistor TR1, repeated descriptions thereof are omitted.

The buffer layer 111 may include an inorganic insulating material such as, for example, silicon nitride (SiNₓ), silicon oxynitride (SiON), or silicon oxide (SiOₓ), and include a single-layered structure or a multi-layered structure including the inorganic insulating materials. The buffer layer 111 may increase flatness of the upper surface of the substrate 100 and prevent or reduce impurities from penetrating a semiconductor layer Act.

The first transistor TR1 may include the semiconductor layer Act, and the semiconductor layer Act may include polycrystalline silicon. Alternatively, the semiconductor layer Act may include amorphous silicon, an oxide semiconductor material, or an organic semiconductor material.

A gate electrode GE may overlap a channel region of the semiconductor layer Act. The gate electrode GE may include a conductive material. As an example, the gate electrode GE may include a conductive material including molybdenum (Mo), aluminum (Al), and titanium (Ti) and have a single-layered structure or a multi-layered structure including the described materials.

The first gate insulating layer 113 between the semiconductor layer Act and the gate electrode GE may include an inorganic insulating material including silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO₂).

The second gate insulating layer 115 may cover the gate electrode GE. Similar to the first gate insulating layer 113, the second gate insulating layer 115 may include an inorganic insulating material including silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂).

A second capacitor electrode CE2 of the storage capacitor Cst may be disposed on the second gate insulating layer 115. The second capacitor electrode CE2 may overlap the gate electrode GE which is below the second capacitor electrode CE2. In this case, the gate electrode GE and the second capacitor electrode CE2 overlapping each other, with the second gate insulating layer 115 between the gate electrode GE and the second capacitor electrode CE2, may constitute the storage capacitor Cst. That is, the gate electrode GE may serve as a first capacitor electrode CE1 of the storage capacitor Cst.

As described herein, the storage capacitor Cst may be disposed such that the storage capacitor Cst overlaps the first transistor TR1. In an embodiment, the storage capacitor Cst may be disposed not to overlap the first transistor TR1.

The second capacitor electrode CE2 may include a conductive material such as, for example, aluminum (Al), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), or copper (Cu), and include a single-layered structure or a multi-layered structure including the described materials.

The interlayer insulating layer 117 may cover the second capacitor electrode CE2. The interlayer insulating layer 117 may include an inorganic insulating material such as, for example, silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). The interlayer insulating layer 117 may include a single-layered structure or a multi-layered structure including the inorganic insulating material.

A drain electrode SD1 and a source electrode SD2 may each be disposed on the interlayer insulating layer 117. The drain electrode SD1 and the source electrode SD2 may each be electrically connected to the semiconductor layer Act through a contact hole formed in the first gate insulating layer 113, the second gate insulating layer 115, and the interlayer insulating layer 117. The drain electrode SD1 and the source electrode SD2 may each include a material having high conductivity. The drain electrode SD1 and the source electrode SD2 may each include a conductive material including molybdenum (Mo), aluminum (Al), copper (Cu), or titanium (Ti) and include a single-layered structure or a multi-layered structure including the described materials. In an embodiment, the drain electrode SD1 and the source electrode SD2 may each have a multi-layered structure of Ti/Al/Ti. In an embodiment, one of the drain electrode SD1 and the source electrode SD2 may be omitted, and a portion of the semiconductor layer Act may be conductive to replace one of the drain electrode SD1 and the source electrode SD2.

The planarization layer 119 may cover the first transistor TR1 and include a contact hole exposing a portion of the first transistor TR1. The planarization layer 119 may include an organic insulating layer. The planarization layer 119 may include an organic insulating material including a general-purpose polymer such as, for example, polymethylmethacrylate (PMMA) or polystyrene (PS), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend thereof.

The first to third light-emitting elements LED1, LED2, and LED3 may be disposed on the pixel circuit layer PCL. The first to third light-emitting elements LED1, LED2, and LED3 may include a quantum-dot light-emitting element and an organic light-emitting element including an emission layer. As an example, the first light-emitting element LED1 and the second light-emitting element LED2 may be quantum-dot light-emitting elements, and the third light-emitting element LED3 may be an organic light-emitting element. However, embodiments of the present disclosure are not limited thereto, and a combination of the quantum-dot light-emitting element and the organic light-emitting element may be variously modified. As an example, the first light-emitting element LED1 may be a quantum-dot light-emitting element, and the second light-emitting element LED2 and the third light-emitting element LED3 may be organic light-emitting elements. A quantum-dot light-emitting element may include an emission layer including quantum dots, and an organic light-emitting element may not include quantum dots and may include an emission layer including an organic material. Hereinafter, for convenience of description, a case where the first light-emitting element LED1 and the second light-emitting element LED2 are quantum-dot light-emitting elements, and the third light-emitting element LED3 is an organic light-emitting element is described.

Each of the first to third light-emitting elements LED1, LED2, and LED3 may include a pixel electrode, an emission layer, and an opposite electrode. In some aspects, each of the first to third light-emitting elements LED1, LED2, and LED3 may further include a first functional layer disposed between the pixel electrode and the emission layer, and a second functional layer disposed between an opposite electrode and the emission layer.

The first light-emitting element LED1 may include the first pixel electrode 211, a first emission layer 221 on the first pixel electrode 211, and an opposite electrode 230 on the first emission layer 221. The first light-emitting element LED1 may further include a first-1 functional layer 215a disposed between the first pixel electrode 211 and the first emission layer 221, and a second-1 functional layer 225a disposed between the opposite electrode 230 and the first emission layer 221.

The second light-emitting element LED2 may include the second pixel electrode 212, a second emission layer 222 on the second pixel electrode 212, and the opposite electrode 230 on the second emission layer 222. The second light-emitting element LED2 may further include a first-2 functional layer 215b disposed between the second pixel electrode 212 and the second emission layer 222, and a second-2 functional layer 225b disposed between the opposite electrode 230 and the second emission layer 222.

The third light-emitting element LED3 may include a third pixel electrode 213, a third emission layer 223, and the opposite electrode 230. The third light-emitting element LED3 may further include a first-3 functional layer 215c disposed between the third pixel electrode 213 and the third emission layer 223, and a second-3 functional layer 225c disposed between the opposite electrode 230 and the second-3 functional layer 225c.

The first pixel electrode 211, the second pixel electrode 212, and the third pixel electrode 213 may be disposed on the pixel circuit layer PCL. The first pixel electrode 211, the second pixel electrode 212, and the third pixel electrode 213 may be disposed on the planarization layer 119. The first pixel electrode 211 may be electrically connected to the drain electrode SD1 or the source electrode SD2 of the first transistor TR1 through a contact hole passing through the planarization layer 119. The first pixel electrode 211, the second pixel electrode 212, and the third pixel electrode 213 may be apart from each other by a preset distance in a first direction (e.g., x direction).

Each of the first pixel electrode 211, the second pixel electrode 212, and the third pixel electrode 213 may be a (semi) light-transmissive electrode or a reflective electrode. Each of the first pixel electrode 211, the second pixel electrode 212, and the third pixel electrode 213 may include a reflective layer and a transparent or semi-transparent electrode layer on the reflective layer, wherein the reflective layer includes at least one of Ag, Mg, Al, Pt, Pd, Au, Ni, Nd, Ir, Cr, or a compound thereof. The transparent or semi-transparent electrode layer may include at least one of indium tin oxide (ITO), indium zinc oxide (IZO), zinc oxide, indium oxide, indium gallium oxide (IGO), or aluminum zinc oxide (AZO). In an embodiment, each of the first pixel electrode 211, the second pixel electrode 212, and the third pixel electrode 213 may include ITO/Ag/ITO.

The display apparatus 1 may further include the pixel-defining layer 120 disposed on the pixel circuit layer PCL. The pixel-defining layer 120 may cover the edges of the first pixel electrode 211, the second pixel electrode 212, and the third pixel electrode 213. The pixel-defining layer 120 may be in direct contact with the upper surface and the lateral surface of the end of each of the first pixel electrode 211, the second pixel electrode 212, and the third pixel electrode 213.

In an embodiment, the pixel-defining layer 120 may include an organic material such as, for example, acryl, benzocyclobutene (BCB), or hexamethyldisiloxane (HMDSO). In another embodiment, the pixel-defining layer 120 may include a photoresist, that is, a photo sensitive resin. Specifically, the pixel-defining layer 120 may include a negative type photoresist in which a reaction such as, for example, cross-linking occurs when exposed to light.

The pixel-defining layer 120 may define a first opening 120OP1 exposing the central portion of the first pixel electrode 211, a second opening 120OP2 exposing the central portion of the second pixel electrode 212, and a third opening 120OP3 exposing the central portion of the third pixel electrode 213. The pixel-defining layer 120 prevents arcs and the like from occurring at the edges of the first pixel electrode 211, the second pixel electrode 212, and the third pixel electrode 213 by increasing a distance between each of the first pixel electrode 211, the second pixel electrode 212, and the third pixel electrode 213 and the opposite electrode 230.

The first emission layer 221 may be disposed inside the first opening 120OP1 of the pixel-defining layer 120. The first emission layer 221 may be disposed on the first-1 functional layer 215a described herein. The second emission layer 222 may be disposed inside the second opening 120OP2 of the pixel-defining layer 120. The second emission layer 222 may be disposed on the first-2 functional layer 215b described herein. The third emission layer 223 may be disposed inside the third opening 120OP3 of the pixel-defining layer 120. The third emission layer 223 may be disposed on the first-3 functional layer 215c described herein.

In an embodiment, the first emission layer 221 and the second emission layer 222 may include an inorganic light-emitting material. As an example, the first emission layer 221 and the second emission layer 222 may include quantum dots. The quantum dots included in the first emission layer 221 and the second emission layer 222 may serve as dopant, and the emission layer may further include a host and/or a delay fluorescent material. The quantum dots denote crystals of a semiconductor compound. The quantum dots may emit light of various light-emitting wavelengths depending on the size of the crystals. The quantum dots may emit light of various light-emitting wavelengths by adjusting an element ratio constituting the quantum dots. As an example, the diameter of the quantum dot may be about 1 nm to about 10 nm.

Quantum dots may be synthesized by a wet chemical process, a metal organic chemical vapor deposition process, a molecular beam epitaxy process, or a similar process. The wet chemical process is a method of mixing an organic solvent with a precursor material and then growing quantum dot crystals. In an example in which the crystal grows, the organic solvent naturally acts as a dispersant coordinated on the surface of the quantum dot crystal and controls the growth of the crystal. Accordingly, the wet chemical process is easier than vapor deposition such as, for example, metal organic chemical vapor deposition (MOCVD) or molecular beam epitaxy (MBE), and may control the growth of the quantum dot particle through a low-cost process.

The quantum dot may include one of a Group II-VI semiconductor compound, a Group III-V semiconductor compound, a Group I-III-VI semiconductor compound, a Group IV-VI semiconductor compound, a Group IV element or compound, and an arbitrary combination thereof.

Examples of the Group II-VI semiconductor compound may include one of a two-element compound including CdS, CdSe, CdTe, ZnS, ZnSe, ZnTe, ZnO, HgS, HgSe, HgTe, MgSe, and MgS; a three-element compound including CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, and MgZnS; and a four-element compound including CdZnSeS, CdZnSeTe, CdZnSTe, CdHgSeS, CdHgSeTe, CdHgSTe, HgZnSeS, HgZnSeTe, and HgZnSTe; and an arbitrary combination thereof.

Examples of the Group III-V semiconductor compound may include one of a two-element compound including GaN, GaP, GaAs, GaSb, AlN, AlP, AlAs, AlSb, InN, InP, InAs, and InSb; a three-element compound including GaNP, GaNAs, GaNSb, GaPAs, GaPSb, AlNP, AlNAs, AlNSb, AlPAs, AlPSb, InGaP, InNP, InAlP, InNAs, InNSb, InPAs, and InPSb; a four-element compound including GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb; and an arbitrary combination thereof. The Group III-V semiconductor compound may further include a Group II element. Examples of the Group III-V semiconductor compound further including a Group II element may include InZnP, InGaZnP, and InAlZnP.

Examples of the Group III-VI semiconductor compound may include one of a two-element compound including GaS, Ga₂S₃, GaSe, Ga₂Se₃, GaTe, InS, InSe, In₂S₃, In₂Se₃, and InTe; and a three-element compound including InGaS₃, and InGaSe₃; or an arbitrary combination thereof.

Examples of the Group I-III-VI semiconductor compound may include one of a three-element compound including AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, and AgAlO₂; a four-element compound including AgInGaS₂, AgInGaSe₂, and CuInGaS; or an arbitrary combination thereof.

Examples of the Group IV-VI semiconductor compound may include one of a two-element compound including SnS, SnSe, SnTe, PbS, PbSe, and PbTe; a three-element compound including SnSeS, SnSeTe, SnSTe, PbSeS, PbSeTe, PbSTe, SnPbS, SnPbSe, and SnPbTe; a four-element compound including SnPbSSe, SnPbSeTe, and SnPbSTe; and an arbitrary combination thereof.

The Group IV element or compound may include one of a single-element including Si and Ge; and a two-element compound including SiC or SiGe; and an arbitrary combination thereof.

Each element included in a multi-element compound such as, for example, a two-element compound, a three-element compound, and a four-element compound may be present in a particle in a uniform concentration or a non-uniform concentration. That is, the chemical formula indicates the type of elements contained in the compound, and the element ratio within the compound may be different. As an example, AgInGaS₂ may denote AgInₓGa₁₋ₓS₂ (x is a real number between 0 and 1).

The quantum dot may have a single structure in which the concentration of each element included in the relevant quantum dot is uniform, or a double structure of a core-shell. As an example, a material of the core may be different from a material of the shell. The shell may cover at least a portion of the core.

The core may include Cd, Zn, Hg, Mg, Ga, AI, In, Sn, Pb, Se, Te, P, or Sb.

The shell of a quantum dot may serve as a protective layer that prevents a chemical change of the core to maintain a semiconductor characteristic and/or serve as a charging layer for giving an electrophoretic characteristic to the quantum dot. The shell may include a single layer or a multi-layer. An interface between the core and the shell may have a concentration gradient in which the concentration of an element existing in the shell reduces toward the center.

Examples of the shell of the quantum dot include oxide of metal or non-metal, a semiconductor compound, or a combination thereof. Examples of oxides of metals or non-metals may include: one of a two-element compound including SiO₂, Al₂O₃, TiO₂, ZnO, MnO, Mn₂O₃, Mn₃O₄, CuO, FeO, Fe₂O₃, Fe₃O₄, CoO, Co₃O₄, and NiO; a three-element compound including MgAl₂O₄, CoFe₂O₄, NiFe₂O₄, and CoMn₂O₄; and an arbitrary combination thereof. Examples of the semiconductor compound may include, as described in the present specification: one of a Group III-VI semiconductor compound; a Group II-VI semiconductor compound; a Group III-V semiconductor compound; a Group III-VI semiconductor compound; a Group I-III-VI semiconductor compound; a Group IV-VI semiconductor compound; and an arbitrary combination thereof. As an example, the semiconductor compound may include one of CdS, CdSe, CdTe, ZnS, ZnSe, ZnTe, ZnSeS, ZnTeS, GaAs, GaP, GaS, GaSe, AgGaS, AgGaS2, GaSb, HgS, HgSe, HgTe, InAs, InP, InGaP, InSb, AlAs, AlP, and AlSb, and an arbitrary combination thereof.

Each element included in a multi-element compound such as, for example, a two-element compound and a three-element compound may be present in a particle in a uniform concentration or a non-uniform concentration. That is, the chemical formula indicates the type of elements contained in the compound, and the element ratio within the compound may be different.

A quantum dot may have a full width at half maximum (FWHM) of a light emission wavelength spectrum of 45 nm or less, specifically about 40 nm or less, and more specifically about 30 nm or less. Within these ranges, color purity or color reproduction may be improved. In some aspects, because light emitted from the quantum dot is emitted in all directions, a viewing angle of light may be improved.

In some aspects, the shape of the quantum dot may be a spherical shape, a pyramid shape, a multi-arm shape, a cubic shape, a nanoparticle, a nanotube, a nanowire, a nanofiber, a nano plate particle, or the like.

Because an energy band gap may be adjusted by adjusting the size of the quantum dot or adjusting an element ratio within a quantum dot compound, light of various wavelength bands may be obtained from a quantum dot emission layer. Accordingly, a light-emitting element emitting light of various wavelengths may be implemented by using the above-described quantum dots (the quantum dots of different sizes are used or an element ratio within a quantum dot compound differs). Specifically, the adjustment of the size of the quantum dot or an element ratio within the quantum dot compound may be selected such that red, green, and/or blue light are emitted. In some aspects, the quantum dots may be configured such that light of various colors is combined to emit white light.

In an embodiment, the third emission layer 223 may include an organic light-emitting material. As an example, the third emission layer 223 may be an emission layer including only an organic material without quantum dots. In an embodiment, the third emission layer 223 including the organic emission material may be denoted by an organic emission layer. Specifically, the third emission layer 223 may include an organic material including a fluorescent or phosphorous material emitting red, green, blue, or white light. The third emission layer 223 may be an organic emission layer including a low-molecular weight organic material or a polymer organic material. As an example, the third emission layer 223 is an organic emission layer and may include copper phthalocyanine, tris-8-hydroxyquinoline aluminum, poly-phenylenevinylene-based material, or polyfluorene-based material.

The first-1 functional layer 215a may be disposed inside the first opening 120OP1 of the pixel-defining layer 120. The first-1 functional layer 215a may be disposed on the first pixel electrode 211. The first-2 functional layer 215b may be disposed inside the second opening 120OP2 of the pixel-defining layer 120. The first-2 functional layer 215b may be disposed on the second pixel electrode 212. The first-3 functional layer 215c may be disposed inside the third opening 120OP3 of the pixel-defining layer 120. The first-3 functional layer 215c may be disposed on the third pixel electrode 213.

In an embodiment, the first-1 functional layer 215a, the first-2 functional layer 215b, and the first-3 functional layer 215c may perform the same function, and the second-1 functional layer 225a, the second-2 functional layer 225b, and the second-3 functional layer 225c may perform the same function. As an example, each of the first-1 functional layer 215a, the first-2 functional layer 215b, and the first-3 functional layer 215c may be a hole transport region, and each of the second-1 functional layer 225a, the second-2 functional layer 225b, and the second-3 functional layer 225c may be an electron transport region. As another example, each of the first-1 functional layer 215a, the first-2 functional layer 215b, and the first-3 functional layer 215c may be an electron transport region, and each of the second-1 functional layer 225a, the second-2 functional layer 225b, and the second-3 functional layer 225c may be a hole transport region.

In another embodiment, the first-1 functional layer 215a and the first-2 functional layer 215b configuring the first and second light-emitting elements LED1 and LED2, which are quantum-dot light-emitting elements, may perform a different function from a function of the first-3 functional layer 215c configuring the third light-emitting element LED3, which is an organic light-emitting element. In this case, the second-1 functional layer 225a and the second-2 functional layer 225b configuring the first and second light-emitting elements LED1 and LED2, which are quantum-dot light-emitting elements, may perform a different function from a function of the second-3 functional layer 225c configuring the third light-emitting element LED3, which is an organic light-emitting element. As an example, the first-1 functional layer 215a and the first-2 functional layer 215b may be hole transport regions, and the first-3 functional layer 215c may be an electron transport region. In this case, the second-1 functional layer 225a and the second-2 functional layer 225b may be electron transport regions, and the second-3 functional layer 225c may be a hole transport region. As another example, the first-1 functional layer 215a and the first-2 functional layer 215b may be electron transport regions, and the first-3 functional layer 215c may be a hole transport region. In this case, the second-1 functional layer 225a and the second-2 functional layer 225b may be hole transport regions, and the second-3 functional layer 225c may be an electron transport region.

The above-described electron transport region may include at least an electron transport layer (ETL) and further include an ETL, a hole blocking layer, or an arbitrary combination thereof. The above-described hole transport region may include at least a hole transport layer (HTL) and further include an HTL, an electron blocking layer, or an arbitrary combination thereof.

In an embodiment, the first-1 functional layer 215a and the second-1 functional layer 225a configuring the first light-emitting element LED1, which is a quantum-dot light-emitting element, may be an inorganic functional layer including an inorganic material. In an embodiment, the first-2 functional layer 215b and the second-2 functional layer 225b configuring the second light-emitting element LED2, which is a quantum-dot light-emitting element, may be an inorganic functional layer including an inorganic material. The first-1 functional layer 215a and the first-2 functional layer 215b may be denoted by first inorganic functional layers, and the second-1 functional layer 225a and the second-2 functional layer 225b may be denoted by second inorganic functional layers.

The inorganic functional layer may include an inorganic hole transport layer or an inorganic electron transport layer. As an example, in the case where the first-1 functional layer 215a and the first-2 functional layer 215b include an inorganic hole transport layer, the second-1 functional layer 225a and the second-2 functional layer 225b may include an inorganic electron transport layer. As another example, in the case where the first-1 functional layer 215a and the first-2 functional layer 215b include an inorganic electron transport layer, the second-1 functional layer 225a and the second-2 functional layer 225b may include an inorganic hole transport layer.

The inorganic hole transport layer may include an inorganic oxide. As an example, the inorganic hole transport layer may include at least one of molybdenum oxide (MoOₓ), vanadium oxide (V₂O₅), hydrogen molybdenum bronze (HxMoO₃), or hydrogen vanadium bronze (HxV₂O₅). In an embodiment, the inorganic hole transport layer may include an inorganic oxide and an organic material. As an example, the inorganic hole transport layer may include an inorganic oxide and may further include an organic compound such as, for example, TaTm (tetra([1,1′-biphenyl]-4-yl)-[1,1′:4′,1″-terphenyl]-4,4″-diamine), TAPC (1,1-Bis[(di-4-tolylamino)phenyl]cyclohexane), or mCP (1,3-Bis(N-carbazolyl)benzene).

The inorganic electron transport layer may include at least an inorganic oxide. As an example, the inorganic electron transport layer may include an inorganic oxide including at least one of titanium oxide (TiO₂), zinc oxide (ZnO), zinc magnesium oxide (ZnMgO), or tin oxide (SnOₓ). In an embodiment, the inorganic electron transport layer may further include cesium (Cs), aluminum (Al), or a combination thereof. In an embodiment, the inorganic electron transport layer may further include an organic material. As an example, the inorganic electron transport layer may include an inorganic oxide and an organic compound including nitrogen. As an example, the inorganic electron transport layer may include an inorganic oxide and an organic compound such as, for example, DPPS (diphenyl-bis[4-(pyridin-3-yl)phenyl]silane), TmPyPB (1,3,5-tri(m-pyrid-3-yl-phenyl)benzene), or Flrpic (Bis[2-(4,6-difluorophenyl)pyridinato-C2,N] (picolinato)iridium).

In an embodiment, the first-3 functional layer 215c and the second-3 functional layer 225c configuring the third light-emitting element LED3, which is an organic light-emitting element, may be an organic functional layer including an organic material. The first-3 functional layer 215c may be denoted by a first organic functional layer, and the second-3 functional layer 225c may be denoted by a second organic functional layer. The organic functional layer may include an organic hole transport layer or an organic electron transport layer. As an example, in the case where the first-3 functional layer 215c includes an organic hole transport layer, the second-3 functional layer 225c may include an organic electron transport layer. As an example, in the case where the first-3 functional layer 215c includes an organic electron transport layer, the second-3 functional layer 225c may include an organic hole transport layer.

The organic hole transport layer may include an organic material. As an example, the organic hole transport layer may include a carbazole-based derivative such as, for example, N-phenylcarbazole, and polyvinylcarbazole, a fluorene-based derivative, a triphenylamine-based derivative such as, for example, TPD(N,N′-bis(3-methylphenyl)-N,N′-diphenyl-[1,1-biphenyl]-4,4′-diamine), and TCTA(4,4′,4″-tris(Ncarbazolyl)triphenylamine), TFB(Poly[(9,9-dioctylfluorenyl-2,7-diyl)-co-(4,4′-(N-(4-sec-butylphenyl)diphenylamine)]), PFO-TPA(poly(fluorine-co-triphenylamine)), TPD-BCB, TCz II, PS-TPD-TFV, Tri-TFV-TCTA, It may include NPB (N,N′-di(1-naphthyl)-N,N′-diphenylbenzidine), TAPC (4,4′-Cyclohexylidene bis[N,N-bis(4-methylphenyl)benzenamine]), or HMTPD (4,4′-Bis[N,N′-(3-tolyl)amino]-3,3′-dimethylbiphenyl).

The organic electron transport layer may include an organic material. As an example, the organic electron transport layer may include Alq3 (Tris(8-hydroxyquinolinato)aluminum), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-ylphenyl)-9,10-dinaphthylanthracene, TPBi(1,3,5-Tri(1-phenyl-1H-benzo[d]imidazol-2-yl)phenyl), BCP (2,9-Dimethyl-4,7-diphenyl-1,10-phenanthroline), Bphen (4,7-Diphenyl-1,10-phenanthroline), TAZ(3-(4-Biphenylyl)-4-phenyl-5-tert-butylphenyl-1,2,4-triazole), NTAZ(4-(Naphthalen-1-yl)-3,5-diphenyl-4H-1,2,4-triazole), tBu-PBD(2-(4-Biphenylyl)-5-(4-tert-butylphenyl)-1,3,4-oxadiazole), BAlq(Bis(2-methyl-8-quinolinolato-N1,O8)-(1,1′-Biphenyl-4-olato)aluminum), Bebq2(berylliumbis(benzoquinolin-10-olate), ADN(9,10-di(naphthalene-2-yl)anthracene), TBCPF(9,9-di(4,4′-bis(3,6-Di-tert-butylcarbazole)-phenyl)-9H-fluorene), B.A., SPPO13(2,7-Bis(diphenylphosphoryl)-9,9), mCPP01(9-(3-(9H-Carbazol-9-yl)phenyl)-3-(diphenylphosphoryl)-9H-carbazole), TPBi(2,2′,2′'-(1,3,5-Benzinetriyl)-tris(1-phenyl-1-H-benzimidazole)), m-PhOTPBi, PFN-OH(poly[9,9-bis(6′-(diethanolamino)hexyl)-fluorene] or mixtures thereof, but is not limited thereto.

The opposite electrode 230 may be disposed on the first emission layer 221 of the first light-emitting element LED1, the second emission layer 222 of the second light-emitting element LED2, and the third emission layer 223 of the third light-emitting element LED3. The opposite electrode 230 may be integrally provided over the entire surface of the substrate 100 and cover the first emission layer 221, the second emission layer 222, and the third emission layer 223. The opposite electrode 230 may include a metal, alloy, electrically conductive compound, or any combination thereof having a low work function. The opposite electrode 230 may include, for example, lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The opposite electrode 230 may be a transmissive electrode, a semi-transmissive electrode, or a reflective electrode. The opposite electrode 230 may have a single-layered structure of a single layer, or a multi-layered structure having a plurality of layers.

In an embodiment, a capping layer 240 may be disposed on the opposite electrode 230. In other words, the capping layer 240 may be disposed on the first to third light-emitting elements LED1, LED2, and LED3. The capping layer 240 may include lithium fluoride (LiF), an inorganic material, and/or an organic material.

In an embodiment, a first auxiliary layer 402 may be disposed on the capping layer 240. The first auxiliary layer 402 may include ethanol (C₂H₆O), a first acidic material, or a second acidic material. Specifically, the first acidic material may be polyacrylic acid (PAA). The second acidic material may be an acidic material of various strengths, ranging from weak acids such as, for example, citric acid (C₆H₈O₇) or acetic acid (CH₃COOH) to strong acids such as, for example, sulfuric acid (H₂SO₄).

Because the auxiliary layer 402 including an acidic material is exposed to an ultraviolet ray and heat during the process of manufacturing the display apparatus, the first auxiliary layer 402 may emit hydrogen ions. Because the emitted hydrogen ions may fill vacancy of the surface of the second functional layer 225 including zinc oxide (ZnO) below the first auxiliary layer 402, traps sites of electrons may be reduced, flow of a current may increase, and the light-emitting efficiency of the display apparatus may increase.

The first auxiliary layer 402 disposed in a plurality of openings 401OP of a first transparent film 401 may be disposed such that the first auxiliary layer 402 overlaps the openings 120OP of the pixel-defining layer 120. The first auxiliary layer 402 disposed in the plurality of openings 401OP of the first transparent film 401 may be disposed such that the first auxiliary layer 402 overlaps emission areas of the first to third light-emitting elements LED1, LED2, and LED3. Specifically, the area of the first auxiliary layer 402 disposed in the plurality of openings 401OP of the first transparent film 401 may be greater than the area of the openings 120OP of the pixel-defining layer 120. Because the first auxiliary layer 402 is disposed such that the first auxiliary layer 402 overlaps the opening 120OP of the pixel-defining layer 120, that is, the emission area of the light-emitting element LED, most of light emitted from the light-emitting element LED passes through the first auxiliary layer 402, the color tone of light may remain uniform, and the brightness and reliability of the display apparatus may be improved.

In an embodiment, the first auxiliary layer 402 may be separately manufactured and inserted on the capping layer 240. As a comparative example, the auxiliary layer may be formed by dropping, onto the capping layer 240, a material for forming the auxiliary layer including ethanol (C₂H₆O), the first acidic material, or the second acidic material. Specifically, the first acidic material may be PAA. The second acidic material may be an acidic material of various strengths, ranging from weak acids such as, for example, citric acid (C₆H₈O₇) or acetic acid (CH₃COOH) to strong acids such as, for example, sulfuric acid (H₂SO₄). In this case, ethanol (C₂H₆O) included in the material for forming the auxiliary layer may dissolve the capping layer 240, and the display apparatus may not emit light. However, in an embodiment, because the first auxiliary layer 402 may be separately manufactured and inserted on the capping layer 240, the first auxiliary layer 402 may be formed without dissolving the capping layer 240.

The display apparatus 1 may have a structure including both a quantum-dot light-emitting element and an organic light-emitting element. The quantum-dot light-emitting element has an advantage of having excellent color coordinates at low manufacturing costs. Compared to the quantum-dot light-emitting element, the organic light-emitting element has an advantage of a long lifespan. Accordingly, in the display apparatus 1 according to an embodiment, because a quantum-dot light-emitting element is used for the first light-emitting element LED1 and the second light-emitting element LED2, and an organic light-emitting element is used for the third light-emitting element LED3, color purity and color reproduction may be improved, high light-emitting characteristics may be achieved, and a long lifespan effect may be simultaneously implemented. However, the disclosure is not limited to the structure in which the first light-emitting element LED1 and the second light-emitting element LED2 include a quantum-dot light-emitting element, and the third light-emitting element LED3 includes an organic light-emitting element, and the first light-emitting element LED1 or the second light-emitting element LED2 may include an organic light-emitting element, and the third light-emitting element LED3 may include a quantum-dot light-emitting element.

In an embodiment, the thin-film encapsulation layer TFE may be disposed on the first to third light-emitting elements LED1, LED2, and LED3. The thin-film encapsulation layer TFE may include at least one inorganic encapsulation layer and at least one organic encapsulation layer. In an embodiment, as illustrated in FIG. 5, the thin-film encapsulation layer TFE may include a first inorganic encapsulation layer 510 on the first to third light-emitting elements LED1, LED2, and LED3, an organic encapsulation layer 520 on the first inorganic encapsulation layer 510, and a second inorganic encapsulation layer 530 on the organic encapsulation layer 520.

The first inorganic encapsulation layer 510 and the second inorganic encapsulation layer 530 may include, for example, an inorganic insulating material among aluminum oxide (Al₂O₃), titanium oxide (TiO₂), tantalum oxide (Ta₂O₅), hafnium oxide (HfO₂), zinc oxide (ZnO), silicon oxide (SiOₓ), silicon nitride (SiNₓ), or silicon oxynitride (SiON). The organic encapsulation layer 520 may include, for example, a polymer-based material. The polymer-based material may include an acryl-based resin, an epoxy-based resin, polyimide, and polyethylene. In an embodiment, the organic encapsulation layer may include acrylate.

Although it is illustrated in FIG. 5 that the light-emitting elements are sealed by the thin-film encapsulation layer TFE, embodiments of the present disclosure are not limited thereto, and in another embodiment, as illustrated in FIG. 3B, the light-emitting elements may be sealed by the sealing member 300 and the sealing substrate 400.

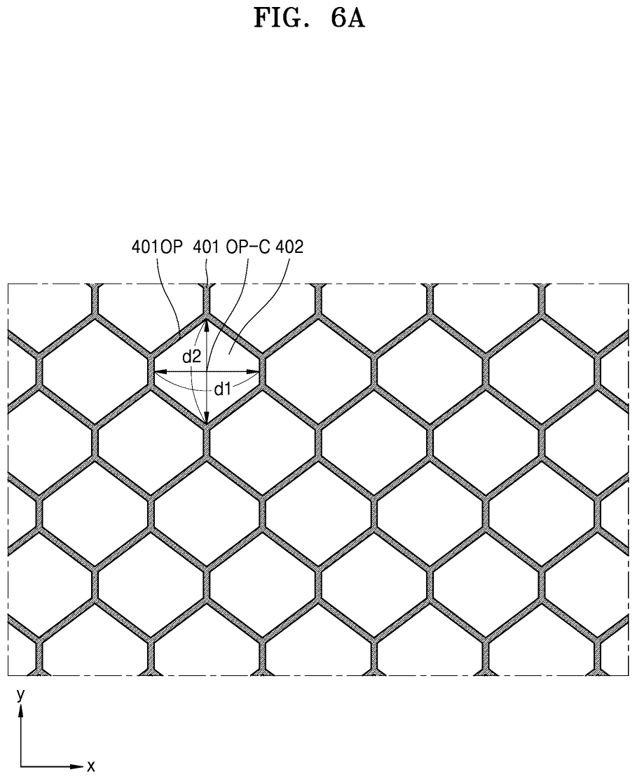

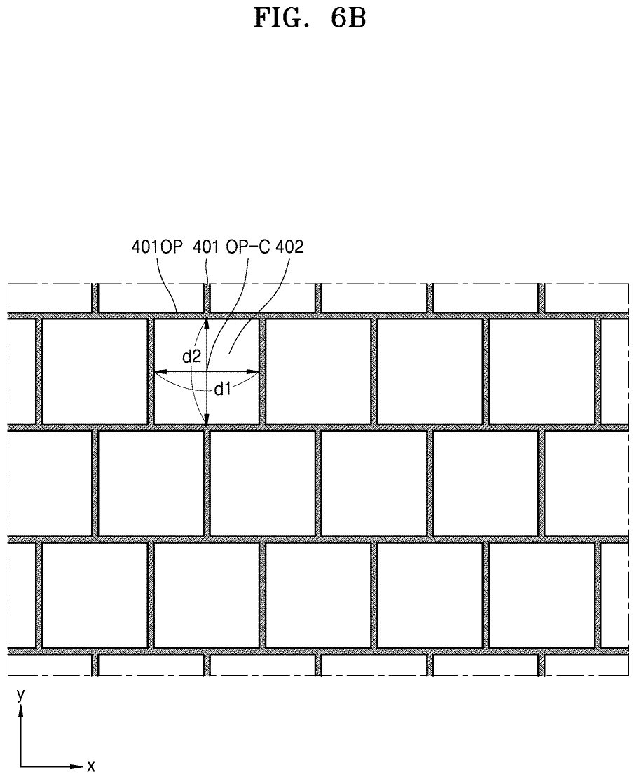

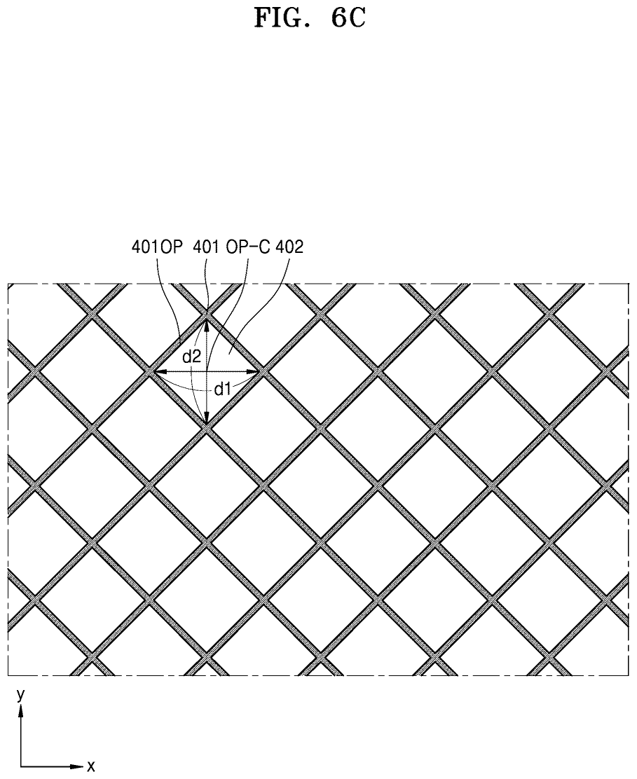

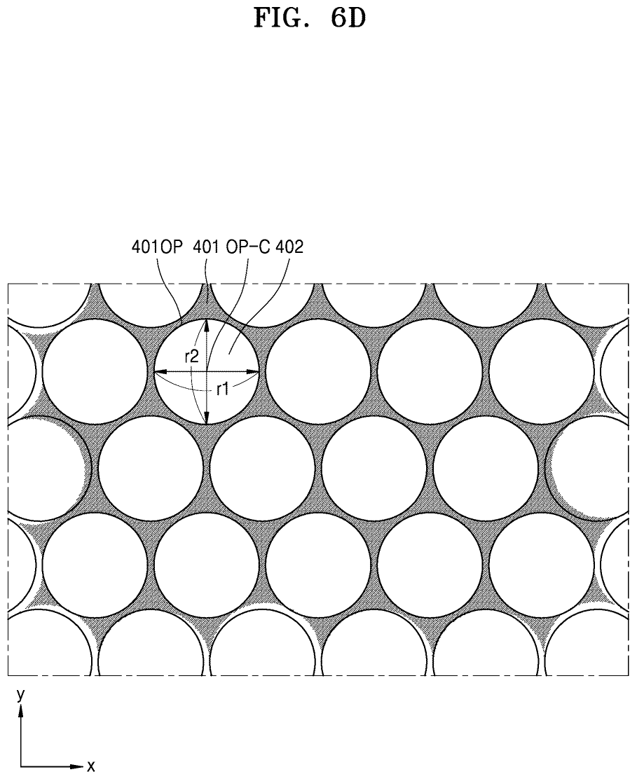

FIGS. 6A to 6D are schematic plan views of the first transparent film 401 and the first auxiliary layer 402 according to embodiments.

Referring to FIGS. 6A to 6D, as described herein, the first transparent film 401 may include the plurality of openings 401OP, and the first auxiliary layer 402 may be disposed in the plurality of openings 401OP of the first transparent film 401.

The first transparent film 401 and the first auxiliary layer 402 may be separately manufactured and disposed on the first to third light-emitting elements LED1, LED2, and LED3, and the capping layer 240. Specifically, the first auxiliary layer 402 may be formed in the plurality of openings 401OP of the first transparent film 401 by filling the plurality of openings 401OP with the material for forming the auxiliary layer using a spray method or coating method and then drying. As described herein, the material for forming the auxiliary layer may include an acidic material. Specifically, the material for forming the auxiliary layer may include an acidic material of various strengths, ranging from weak acids such as, for example, citric acid (C₆H₈O₇) or acetic acid (CH₃COOH) to strong acids such as, for example, sulfuric acid (H₂SO₄). In some aspects, the material for forming the auxiliary layer may include ethanol or PAA.

In a case of forming the auxiliary layer by forming the material for forming the auxiliary layer on the capping layer 240 and then drying the same, the capping layer 240 may be dissolved and damaged, and the reliability and quality of the display apparatus 1 may deteriorate. In an embodiment, in the case of separately manufacturing the first auxiliary layer 402 and then disposing the first auxiliary layer 402 between the capping layer 240 and the thin-film encapsulation layer TFE, because the first auxiliary layer 402 may be formed without damage to the capping layer 240, the reliability and quality of the display apparatus may be improved.

Each of the plurality of openings 401OP of the first transparent film 401 may be provided in a polygonal shape. As illustrated in FIGS. 6A to 6C, in an embodiment, the plurality of openings 401OP of the first transparent film 401 may be provided in a hexagonal shape, a quadrangular shape, or a rhombus shape. A diameter d1 in the first direction (e.g., x direction or −x direction), and a diameter d2 in a second direction (e.g., y direction or −y direction) of the opening 401OP having a polygonal shape may be 10 μm or more. The diameter d1 in the first direction (e.g., x direction or −x direction) may be a length of a line passing through a center OP-C of the opening 401OP of the first transparent film 401 and extending in the first direction (e.g., x direction or −x direction), and the diameter d2 in the second direction (e.g., y direction or −y direction) may be a length of a line passing through a center OP-C of the opening 401OP of the first transparent film 401 and extending in the second direction (e.g., y direction or −y direction). In the case where the diameter d1 in the first direction (e.g., x direction or −x direction), or the diameter d2 in the second direction (e.g., y direction or −y direction) of the opening having a polygonal shape is less than 10 μm, fairness (or ease) of the manufacturing process of forming the first auxiliary layer 402 by filling the plurality of openings 401OP of the first transparent film 401 with the material for forming the auxiliary layer and then drying the same, may not be secured.

As illustrated in FIG. 6D, in an embodiment, the plurality of openings 401OP of the first transparent film 401 may be provided in a circular shape. A diameter r1 in the first direction (e.g., x direction or −x direction), and a diameter r2 in the second direction (e.g., y direction or −y direction) of the opening 401OP having a circular shape may be 10 μm or more. The diameter r1 in the first direction (e.g., x direction or −x direction) may be a length of a line passing through the center OP-C of the opening 401OP of the first transparent film 401 and extending in the first direction (e.g., x direction or −x direction), and the diameter r2 in the second direction (e.g., y direction or −y direction) may be a length of a line passing through the center OP-C of the opening 401OP of the first transparent film 401 and extending in the second direction (e.g., y direction or −y direction). In the case where the diameter r1 in the first direction (e.g., x direction or −x direction), or the diameter r2 in the second direction (e.g., y direction or −y direction) of the opening 401OP having a circular shape is less than 10 μm, fairness (or ease) of the manufacturing process of forming the first auxiliary layer 402 by filling the plurality of openings 401OP of the first transparent film 401 with the material for forming the auxiliary layer and then drying the same, may not be secured.

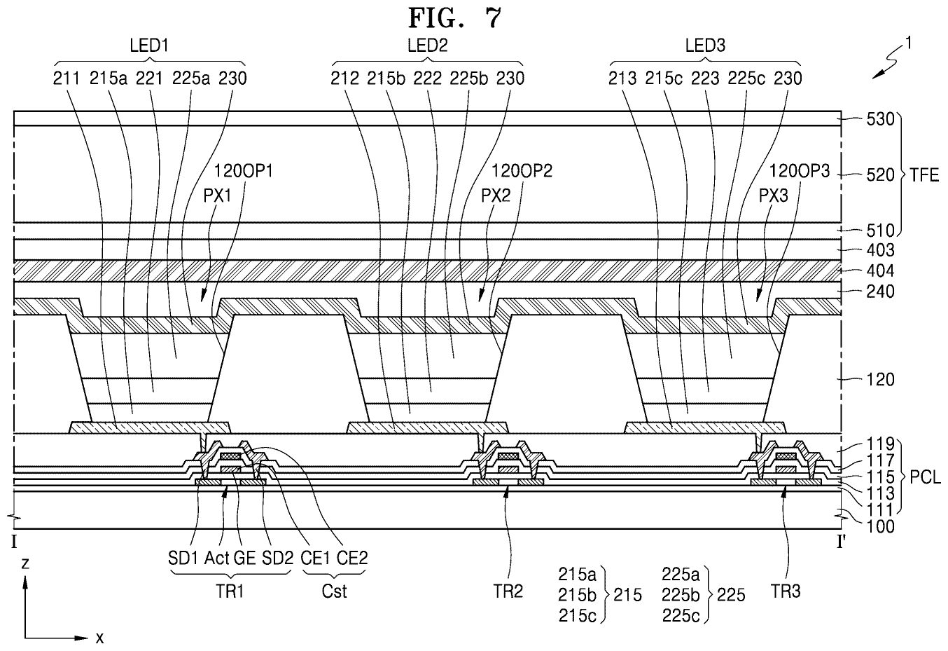

FIG. 7 is a schematic cross-sectional view of a display apparatus according to an embodiment, taken along line I-I′ of FIG. 4.

Referring to FIG. 7, a second auxiliary layer 404 may be disposed on the capping layer 240. A second transparent film 403 may be disposed on the auxiliary layer 404. The auxiliary layer 404 may be a structure attached to the lower surface of the second transparent film 403. The second transparent film 403 may include polyvinyl chloride (PVC). The second auxiliary layer 404 may include an acidic material. The second auxiliary layer 404 may include ethanol or PAA. Because the second auxiliary layer 404 includes an acidic material, hydrogen ions may be emitted, and the emitted hydrogen ions may fill vacancy of the second functional layer 225 below the second auxiliary layer 404. Accordingly, trap sites of electrons may be reduced, flow of a current may increase, and the light-emitting efficiency of the display apparatus may increase.

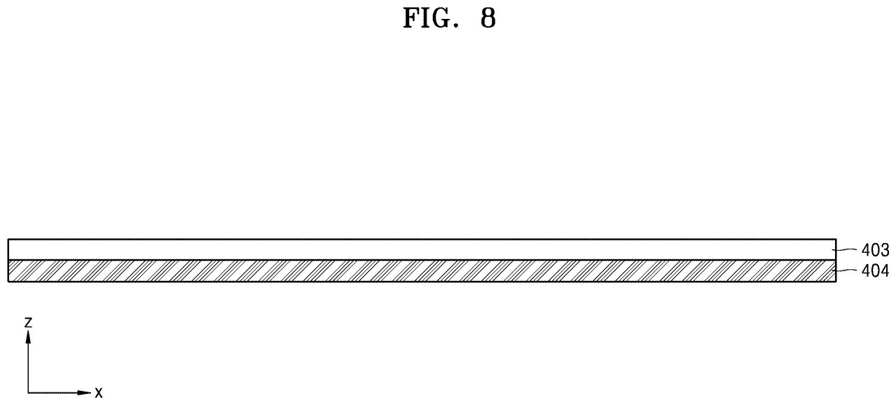

FIG. 8 is a schematic cross-sectional view of the second transparent film 403 and the second auxiliary layer 404. Referring to FIG. 8, the second transparent film 403 and the second auxiliary layer 404 may be separately manufactured and disposed on the first to third light-emitting elements LED1, LED2, and LED3, and the capping layer 240. The material for forming the second auxiliary layer 404 may be coated onto one surface of the second transparent film 403, and then dried to form the second auxiliary layer 404. The material for forming the second auxiliary layer 404 may include an acidic material. In some aspects, the material for forming the second auxiliary layer 404 may include ethanol or PAA.

In a case of forming the second auxiliary layer 404 by forming the material for forming the second auxiliary layer 404 on the capping layer 240 and then drying the same, the capping layer 240 may be dissolved and damaged, and the reliability and quality of the display apparatus may deteriorate. In an embodiment, in the case of separately manufacturing the second auxiliary layer 404 and then disposing the second auxiliary layer 404 between the capping layer 240 and the thin-film encapsulation layer TFE, because the second auxiliary layer 404 may be formed without damage to the capping layer 240, the reliability and quality of the display apparatus may be improved.

In an embodiment, because the first auxiliary layer 402 including an acidic material disposed in the plurality of openings 401OP of the first transparent film 401, or the second auxiliary layer 404 coated onto the entire lower surface of the second transparent film 403 is separately manufactured and disposed on the capping layer 240 such that the first auxiliary layer 402 or the second auxiliary layer 404 overlaps the openings of the pixel-defining layer 120, hydrogen ions emitted from the first auxiliary layer 402 and the second auxiliary layer 404 may fill vacancy of the functional layer without damage to the capping layer 240, and accordingly, flow of a current may increase and the reliability and quality of the display apparatus may be improved.

According to an embodiment having the above configuration, the display apparatus with improved reliability and quality may be implemented. However, the scope of the disclosure is not limited by this effect.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate;
a pixel-defining layer comprising an opening and disposed on the substrate;
a light-emitting element overlapping the opening of the pixel-defining layer and comprising a pixel electrode, an emission layer, and an opposite electrode;
a capping layer disposed on the light-emitting element;
a transparent film disposed on the capping layer and comprising a plurality of openings; and
an auxiliary layer disposed in the plurality of openings of the transparent film and overlapping the opening of the pixel-defining layer.

2. The display apparatus of claim 1, wherein respective areas of the auxiliary layer disposed in the plurality of openings of the transparent film are each greater than an area of the opening of the pixel-defining layer.

3. The display apparatus of claim 1, wherein the auxiliary layer comprises at least one of citric acid (C₆H₈O₇), acetic acid (CH₃COOH), or sulfuric acid (H₂SO₄).

4. The display apparatus of claim 1, wherein the auxiliary layer comprises polyacrylic acid (PAA).

5. The display apparatus of claim 1, wherein the auxiliary layer comprises ethanol.

6. The display apparatus of claim 1, wherein each of the plurality of openings of the transparent film is provided in a polygonal shape.

7. The display apparatus of claim 6, wherein each of the plurality of openings of the transparent film is provided in a hexagonal shape.

8. The display apparatus of claim 6, wherein each of the plurality of openings of the transparent film is provided in a quadrangular shape.

9. The display apparatus of claim 6, wherein each of the plurality of openings of the transparent film is provided in a rhombus shape.

10. The display apparatus of claim 1, wherein each of the plurality of openings of the transparent film is provided in a circular shape.

11. The display apparatus of claim 1, wherein the emission layer comprises quantum dots.

12. The display apparatus of claim 1, wherein a diameter of each of the plurality of openings of the transparent film is 10 μm or more.

13. The display apparatus of claim 1, wherein the transparent film comprises polyvinyl chloride (PVC).

14. The display apparatus of claim 1, further comprising a thin-film encapsulation layer disposed on the auxiliary layer and the transparent film.

15. A display apparatus comprising:
a substrate;
a pixel-defining layer comprising an opening and disposed on the substrate;
a light-emitting element overlapping the opening of the pixel-defining layer and comprising a pixel electrode, an emission layer, and an opposite electrode;
a capping layer disposed on the light-emitting element;
an auxiliary layer disposed on the capping layer and comprising an acidic material; and
a transparent film disposed on the auxiliary layer, wherein the auxiliary layer is attached to a lower surface of the transparent film.

16. The display apparatus of claim 15, wherein the auxiliary layer is coated onto an entirety of the lower surface of the transparent film.

17. The display apparatus of claim 15, wherein the auxiliary layer comprises an acidic material.

18. The display apparatus of claim 15, wherein the auxiliary layer comprises ethanol.

19. The display apparatus of claim 15, wherein the emission layer comprises quantum dots.

20. The display apparatus of claim 15, further comprising a thin-film encapsulation layer disposed on the transparent film.

21. An electronic device comprising:
a display apparatus comprising:
a substrate;
a pixel-defining layer comprising an opening and disposed on the substrate;
a light-emitting element overlapping the opening of the pixel-defining layer and comprising a pixel electrode, an emission layer, and an opposite electrode;
a capping layer disposed on the light-emitting element;
a transparent film disposed on the capping layer and comprising a plurality of openings; and
an auxiliary layer disposed in the plurality of openings of the transparent film and overlapping the opening of the pixel-defining layer.
